(19) United States
(12) Patent Application Publication
(10) Pub. No.: US 2026/0371528 A1
(43) Pub. Date: Nov. 19, 2026

(54) HEAT PIPE AND ELECTRONIC DEVICE

(71) Applicant: Micas Networks Inc., SAN JOSE, CA (US)

(72) Inventors: Wei LIU, SAN JOSE, CA (US); Guohong LAI, SAN JOSE, CA (US)

(73) Assignee: Micas Networks Inc., SAN JOSE, CA (US)

(21) Appl. No.: 19/724,061

(22) Filed: Jun. 29, 2026

Related U.S. Application Data
(63) Continuation of application No. PCT/CN2026/083985, filed on Mar. 17, 2026.

(30) Foreign Application Priority Data
May 13, 2025 (CN) 202520933891.X

(51) Int. Cl. H05K 7/20

(52) U.S. Cl. CPC H05K 7/20336

(57) ABSTRACT

This application relates to a heat pipe and an electronic device. The heat pipe includes: a tube body provided with an accommodating cavity, where the tube body includes an evaporation section, an adiabatic section, and a condensation section sequentially arranged along an extension direction of the tube body, and a heat-conducting working medium is provided in the accommodating cavity; and a capillary structure disposed in the accommodating cavity and connected to the tube body, including: a first sub-capillary structure disposed in the evaporation section; a second sub-capillary structure disposed in the adiabatic section; and a third sub-capillary structure disposed in the condensation section, where a pore radius of at least one of the first sub-capillary structure or the third sub-capillary structure is less than a pore radius of the second sub-capillary structure.

### CROSS-REFERENCE TO RELATED APPLICATIONS

This application is a continuation of International Application No. PCT/CN2026/083985, which claims priority to Chinese Patent Application No. 202520933891.X, filed with the China National Intellectual Property Administration on May 13, 2025 and entitled "HEAT PIPE AND ELECTRONIC DEVICE", both which are incorporated herein by reference in their entireties.

### TECHNICAL FIELD

This application relates to the field of heat dissipation technologies, and in particular, to a heat pipe and an electronic device.

### BACKGROUND

A network device may include a switching chip and an optical module. In the network device, the switching chip is a core component that implements data switching and transmission, and can perform operations such as data reception, storage, analysis, and forwarding. A main function of the optical module is to implement photoelectric conversion. Because temperature resistance specifications of the switching chip and the optical module are different, the switching chip and the optical module cannot share a heat sink. In an air-cooling architecture, due to a space limitation of the network device, a heat pipe is required to transfer heat of the optical module from a space-limited area in which the optical module is located to a relatively spacious area, so that local overheating can be avoided.

In a related technology, the heat pipe includes an evaporation section and a condensation section, and a working medium and a capillary structure are provided in the heat pipe. The working medium is a medium substance for heat transfer. The working medium absorbs heat and evaporates in the evaporation section, flows to the condensation section, and then condenses to release the heat, thereby achieving efficient heat transfer through a phase change cycle of the working medium.

### SUMMARY

Exemplary embodiments of this application provide a heat pipe and an electronic device.

According to a first aspect, an embodiment of this application provides a heat pipe, including:
a tube body provided with an accommodating cavity, where the tube body includes an evaporation section, an adiabatic section, and a condensation section sequentially arranged along an extension direction of the tube body, and a heat-conducting working medium is provided in the accommodating cavity; and
a capillary structure disposed in the accommodating cavity and connected to the tube body, including:
   a first sub-capillary structure disposed in the evaporation section;
   a second sub-capillary structure disposed in the adiabatic section; and
   a third sub-capillary structure disposed in the condensation section, where
   a pore radius of at least one of the first sub-capillary structure or the third sub-capillary structure is less than a pore radius of the second sub-capillary structure.

In the heat pipe provided in this embodiment of this application, the pore radius of at least one of the first sub-capillary structure or the third sub-capillary structure is less than the pore radius of the second sub-capillary structure. A smaller pore radius of the capillary structure in the evaporation section can improve capillary force of the evaporation section and reduce evaporation thermal resistance; a smaller pore radius of the capillary structure in the condensation section can reduce condensation thermal resistance; and a larger pore radius of the capillary structure in the adiabatic section can widen a flow channel of the heat-conducting working medium in the adiabatic section, thereby helping reduce flow resistance of the heat-conducting working medium in the capillary structure in the adiabatic section. Therefore, the heat pipe can have a larger heat transfer limit and lower thermal resistance, thereby helping improve heat conduction performance of the heat pipe.

In an embodiment, the pore radius of at least one of the first sub-capillary structure or the third sub-capillary structure is less than or equal to a first threshold, and the first threshold ranges from 30 μm to 36 μm.

In an embodiment, the pore radius of the second sub-capillary structure is greater than the first threshold, and the first threshold ranges from 30 μm to 36 μm.

In an embodiment, the first sub-capillary structure includes a first sintered powder, the second sub-capillary structure includes a second sintered powder, and the third sub-capillary structure includes a third sintered powder; and a mesh size of at least one of the first sintered powder or the third sintered powder is greater than a mesh size of the second sintered powder.

In an embodiment, the first sub-capillary structure includes a first metal mesh, the second sub-capillary structure includes a second metal mesh, and the third sub-capillary structure includes a third metal mesh; and a mesh size of at least one of the first metal mesh or the third metal mesh is greater than a mesh size of the second metal mesh.

In an embodiment, a thickness of at least one of the first sub-capillary structure or the third sub-capillary structure is less than a thickness of the second sub-capillary structure.

In an embodiment, the tube body includes a first transition section, the first transition section connects the evaporation section and the adiabatic section, and the capillary structure further includes a fourth sub-capillary structure disposed in the first transition section; and

a pore radius of the fourth sub-capillary structure gradually decreases along a direction from the adiabatic section to the evaporation section; and/or

a thickness of the fourth sub-capillary structure gradually decreases along a direction from the adiabatic section to the evaporation section.

In an embodiment, the tube body includes a second transition section, the second transition section connects the condensation section and the adiabatic section, and the capillary structure further includes a fifth sub-capillary structure disposed in the second transition section; and

a pore radius of the fifth sub-capillary structure gradually decreases along a direction from the adiabatic section to the condensation section; and/or

a thickness of the fifth sub-capillary structure gradually decreases along a direction from the adiabatic section to the condensation section.

In an embodiment, at least one of the first sub-capillary structure or the third sub-capillary structure is provided with at least one groove on a side facing away from the tube body.

In an embodiment, the at least one groove includes a first groove, and the first groove extends along the extension direction of the tube body.

In an embodiment, the at least one groove further includes a second groove, the second groove extends along the extension direction of the tube body, and the first groove and the second groove are spaced apart along a circumferential direction of the tube body.

In an embodiment, the at least one groove includes a third groove, and the third groove extends along the circumferential direction of the tube body.

In an embodiment, the at least one groove further includes a fourth groove, and the third groove and the fourth groove are spaced apart along the extension direction of the tube body.

In an embodiment, a groove depth of the at least one groove gradually increases in a direction from a center to an edge of the tube body; and/or

an opening dimension of the at least one groove gradually increases in a direction from a groove bottom wall to an opening of the at least one groove.

In an embodiment, the tube body includes a first tube wall and a second tube wall that are opposite to each other and spaced apart, and the first tube wall is in thermal conduction with a heat-generating element; and

a thickness of a part of the capillary structure on the first tube wall is less than or equal to a thickness of a part of the capillary structure on the second tube wall.

In an embodiment, the thickness of the part of the capillary structure on the first tube wall is less than thicknesses of parts of the first sub-capillary structure and the second sub-capillary structure on the second tube wall.

In an embodiment, the tube body includes a third tube wall and a fourth tube wall that are opposite to each other and spaced apart, and the third tube wall and the fourth tube wall are respectively connected to the first tube wall and the second tube wall to form the accommodating cavity; and thicknesses of parts of the third sub-capillary structure on the second tube wall, the third tube wall, and the fourth tube wall are all less than the thicknesses of the parts of the first sub-capillary structure and the second sub-capillary structure on the second tube wall.

In an embodiment, the tube body is provided with a first engaging portion on a side facing toward the capillary structure, the capillary structure is provided with a second engaging portion on a side facing toward the tube body, and the first engaging portion cooperates with the second engaging portion to fasten the capillary structure to the tube body.

In an embodiment, one of the first engaging portion and the second engaging portion is an engaging groove, and the other is an engaging protrusion, where the engaging protrusion is disposed in the engaging groove, and preferably, an opening dimension of the engaging groove gradually decreases along a direction from a groove bottom wall to an opening of the engaging groove. According to a second aspect, an embodiment of this application provides an electronic device, including a heat-generating element and the heat pipe according to the first aspect, where the heat-generating element is in thermal conduction with the evaporation section of the heat pipe.

### BRIEF DESCRIPTION OF DRAWINGS

To describe technical solutions in embodiments or exemplary embodiments of this application more clearly, the following briefly describes accompanying drawings used in describing the embodiments or exemplary embodiments. Clearly, the accompanying drawings in the following descriptions are merely some embodiments of this application, and a person of ordinary skill in the art may still derive other drawings from these accompanying drawings without creative efforts.

FIG. 1 is a cross-sectional view of a heat pipe according to an embodiment of this application.

FIG. 2 is a cross-sectional view of a heat pipe according to another embodiment of this application.

FIG. 3 is a cross-sectional view taken along line A-A of FIG. 2.

FIG. 4 is a cross-sectional view of a heat pipe according to still another embodiment of this application.

FIG. 5 is a cross-sectional view of a heat pipe according to still another embodiment of this application.

FIG. 6 is a cross-sectional view taken along line B-B of FIG. 5.

FIG. 7 is a cross-sectional view of a heat pipe according to still another embodiment of this application.

FIG. 8 is a cross-sectional view of a heat pipe according to still another embodiment of this application.

Reference numerals:

100. heat pipe; 110. tube body; 110a. evaporation section; 110b. adiabatic section; 110c. condensation section; 110d. first transition section; 110e. second transition section; 111. first tube wall; 112. second tube wall; 113. third tube wall; 114. fourth tube wall; 115. accommodating cavity; 120. capillary structure; 121. groove; 1221. first sub-capillary structure; 1222. second sub-capillary structure; 1223. third sub-capillary structure; 1224. fourth sub-capillary structure; 1225. fifth sub-capillary structure; 200. heat-generating element.

### DESCRIPTION OF EMBODIMENTS

To make the objectives, features, and advantages of this application more apparent and more readily understandable, the following describes specific implementations of this application in detail with reference to the accompanying drawings. In the following description, many specific details are set forth to provide a thorough understanding of this application. However, this application can be implemented in a plurality of other ways different from those described herein, and a person skilled in the art can make similar improvements without departing from the essence of this application. Therefore, this application is not limited by the specific implementations disclosed below.

In the description of this application, it should be understood that if terms such as "center", "longitudinal", "transverse", "length", "width", "thickness", "upper", "lower", "front", "rear", "left", "right", "vertical", "horizontal", "top", "bottom", "inside", "outside", "clockwise", "counterclockwise", "axial", "radial", and "circumferential" appear, orientations or positional relationships indicated by these terms are based on orientations or positional relationships shown in the accompanying drawings. The terms are merely intended to facilitate the description of this application and simplify the description, rather than indicating or implying that the apparatuses or components referred to in this application need to have specific orientations, or be constructed and operated in a specific orientation. Therefore, the terms shall not be construed as limitations on this application.

In addition, if terms such as "first" and "second" appear, these terms are merely for the purpose of description, and shall not be understood as any indication or implication of relative importance or any implicit indication of a quantity of indicated technical features. Therefore, a feature defined by "first" or "second" may explicitly or implicitly include at least one feature. In the description of this application, if the term "a plurality of" appears, the term "a plurality of" means at least two, for example, two or three, unless otherwise clearly and specifically defined.

In this application, unless otherwise clearly specified and defined, if terms such as "mount", "connect", "join", and "fasten" appear, these terms should be understood in a broad sense. For example, the terms may refer to a fixed connection, a detachable connection, or integration, may refer to a mechanical connection or an electrical connection, or may refer to a direct connection, an indirect connection through an intermediate medium, internal communication between two components, or an interaction relationship between two components, unless otherwise clearly defined. For a person of ordinary skill in the art, specific meanings of the foregoing terms in this application may be understood based on specific circumstances.

In this application, unless otherwise clearly specified and defined, if descriptions such as a first feature being "on" or "under" a second feature appear, the descriptions may mean that the first feature and the second feature are in direct contact, or that the first feature and the second feature are in indirect contact through an intermediate medium. Moreover, the first feature being "above", "over", or "on top of" the second feature may mean that the first feature is directly above or obliquely above the second feature, or may merely indicate that the first feature is at a higher horizontal level than the second feature. The first feature being "below", "under", or "beneath" the second feature may mean that the first feature is directly below or obliquely below the second feature, or may merely indicate that the first feature is at a lower horizontal level than the second feature.

It should be noted that if a component is referred to as being "fastened to" or "disposed on" another component, it may be directly fastened to the other component, or there may be a component in between. If a component is considered as being "connected to" another component, it may be directly connected to the other component, or there may be a component in between. If present, the terms "vertical", "horizontal", "upper", "lower", "left", "right", and similar expressions used in this application are for illustrative purposes only and do not represent the only implementations.

It should be noted that "at least one" in this application includes any combination of elements indicated thereby. For example, at least one of A, B, or C includes A alone, B alone, C alone, A and B, A and C, B and C, and A, B, and C.

In a related technology, a network device may include a switching chip and an optical module. In the network device, the switching chip is a core component that implements data switching and transmission, and can perform operations such as data reception, storage, analysis, and forwarding. A main function of the optical module is to implement photoelectric conversion. The switching chip and the optical module may use a near packaged optics (Near Packaged Optics, NPO) technology, a co-packaged optics (Co-packaged Optics, CPO) technology, or the like. CPO is a technology that integrates the switching chip and the optical module in a same package. CPO shortens an electrical signal transmission distance, optimizes a system architecture, and significantly reduces power consumption, but heat thereof is relatively concentrated.

Because temperature resistance specifications of the switching chip and the optical module are different, many problems may arise when the switching chip and the optical module share a heat sink. In an air-cooling architecture, due to a space limitation of the network device, a heat pipe is required to transfer heat of the optical module from a space-limited area in which the optical module is located to a relatively spacious area, so that local overheating can be avoided.

The heat pipe includes an evaporation section, an adiabatic section, and a condensation section that are sequentially connected, and a working medium and a capillary structure are provided in the heat pipe. The working medium is a medium substance for heat transfer. The working medium absorbs heat and evaporates in the evaporation section, flows to the condensation section, then condenses to release the heat, and flows back under capillary force of the capillary structure, thereby achieving efficient heat transfer through a phase change cycle of the working medium.

In related designs, a uniform capillary structure is used in the evaporation section, the adiabatic section, and the condensation section, and pore radii therein are consistent.

In some other related designs, to reduce flow resistance of the working medium in the capillary structure in the adiabatic section, a capillary structure with a larger pore radius may be used. However, when the pore radius of the capillary structure is larger, capillary force of the capillary structure in the evaporation section may be reduced, which is not conducive to the return flow of the working medium. In addition, evaporation thermal resistance of the evaporation section and condensation thermal resistance of the condensation section increase, affecting heat conduction performance of the heat pipe.

In still some other related designs, a capillary structure with a smaller pore radius is used to improve capillary force of the capillary structure in the evaporation section and reduce evaporation thermal resistance, but this may cause an increase in flow resistance of the working medium in the capillary structure in the adiabatic section.

Therefore, a contradiction between capillary force and flow resistance exists in the uniform capillary structure, resulting in a mutual constraint between an ultimate heat dissipation capability and thermal resistance of the heat pipe, and hindering further improvement of heat pipe performance.

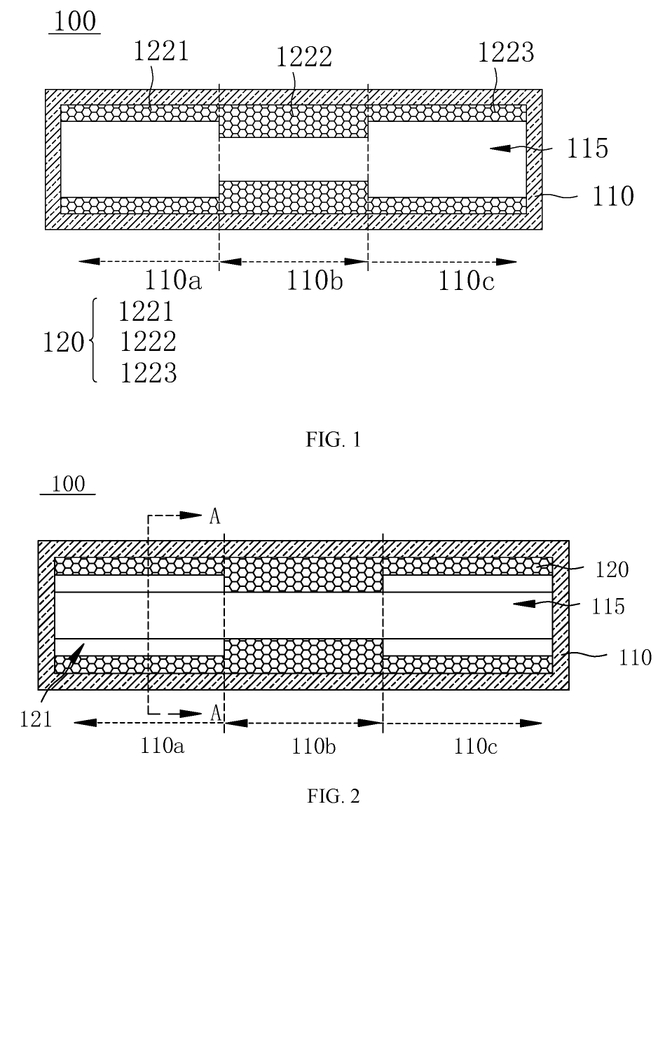

A heat pipe 100 and an electronic device provided in embodiments of this application are hereinafter described with reference to FIG. 1 to FIG. 7.

With reference to FIG. 1, an embodiment of this application provides a heat pipe 100. The heat pipe 100 includes a tube body 110 and a capillary structure 120. The tube body 110 is provided with an accommodating cavity 115. The tube body 110 includes an evaporation section 110a, an adiabatic section 110b, and a condensation section 110c sequentially arranged along an extension direction of the tube body 110. The accommodating cavity 115 is configured to accommodate a heat-conducting working medium. The capillary structure 120 is disposed in the accommodating cavity 115 of the evaporation section 110a, the adiabatic section 110b, and the condensation section 110c, and the capillary structure 120 is connected to the tube body 110.

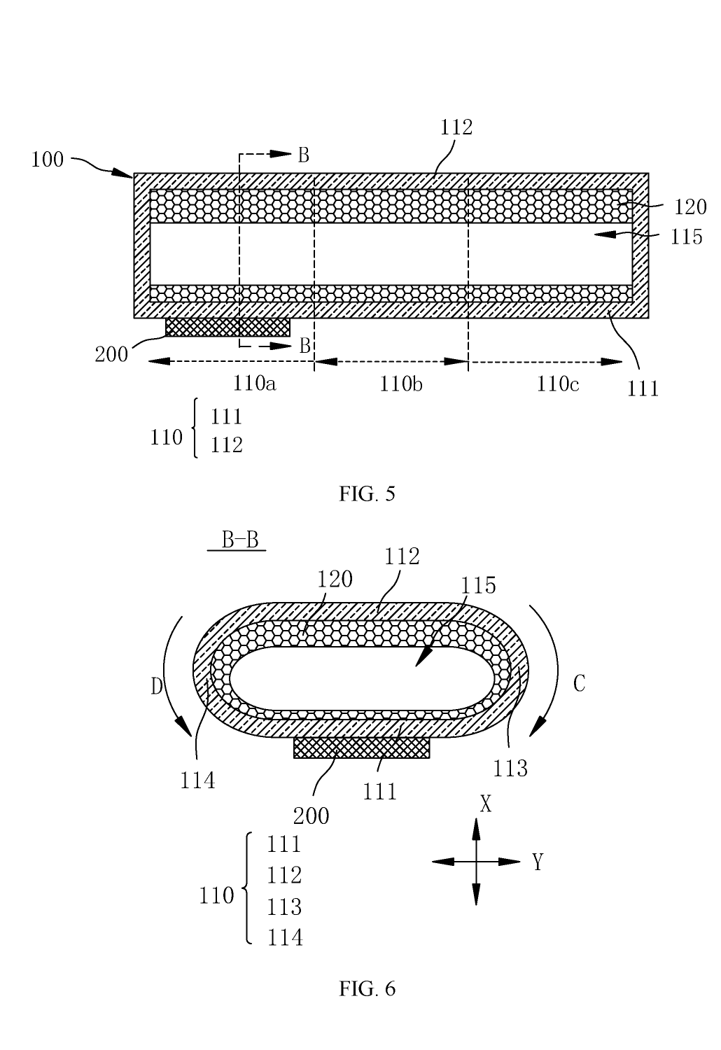

For example, the evaporation section 110a is configured to absorb heat from a heat-generating element 200 (located at a position below the evaporation section 110a shown in FIG. 5). When the heat is transferred from the heat-generating element 200 into the evaporation section 110a, a liquid heat-conducting working medium in the capillary structure 120 absorbs the heat and evaporates into a gaseous heat-conducting working medium. The gaseous heat-conducting working medium rapidly flows to the condensation section 110c in low-pressure space inside the heat pipe 100. In the condensation section 110c, the gaseous heat-conducting working medium releases heat and condenses into a liquid heat-conducting working medium. Then the liquid heat-conducting working medium flows back to the evaporation section 110a under capillary force of the capillary structure 120. The cycle is repeated to achieve continuous heat transfer.

A pore radius of at least one of the capillary structure 120 in the evaporation section 110a or the capillary structure 120 in the condensation section 110c is less than a pore radius of the capillary structure 120 in the adiabatic section 110b. In this way, the pore radius of at least one of the capillary structure 120 in the evaporation section 110a and the capillary structure 120 in the condensation section 110c can be made smaller, which can improve the capillary force of the capillary structure 120 in the evaporation section 110a and the condensation section 110c. In addition, the pore radius of the capillary structure 120 in the adiabatic section 110b can be made larger, which widens a flow channel of the heat-conducting working medium in the adiabatic section 110b, thereby helping reduce flow resistance of the heat-conducting working medium in the capillary structure 120 in the adiabatic section 110b. Therefore, the heat pipe 100 can have a larger heat transfer limit and lower thermal resistance, thereby helping improve heat conduction performance of the heat pipe 100. The capillary structure 120 includes a first sub-capillary structure 1221, a second sub-capillary structure 1222, and a third sub-capillary structure 1223. The first sub-capillary structure 1221 is disposed in the evaporation section 110a, the second sub-capillary structure 1222 is disposed in the adiabatic section 110b, and the third sub-capillary structure 1223 is disposed in the condensation section 110c. A pore radius of at least one of the first sub-capillary structure 1221 or the third sub-capillary structure 1223 is less than a pore radius of the second sub-capillary structure 1222.

The pore radius may be an equivalent pore radius, and the equivalent pore radius may refer to an effective radius of a pore inside a porous material.

For example, selection of the heat-conducting working medium may be determined based on a combination of an operating temperature of the heat pipe 100 and a material of the tube body 110 of the heat pipe 100. For example, the heat-conducting working medium may include deionized water, ammonia, or a refrigerant.

For example, the pore radius of at least one of the capillary structure 120 in the evaporation section 110a or the capillary structure 120 in the condensation section 110c is less than or equal to a first threshold, and the first threshold ranges from 30 μm to 36 μm. In this way, the pore radius of at least one of the capillary structure 120 in the evaporation section 110a or the capillary structure 120 in the condensation section 110c is made smaller, which can improve the capillary force of the capillary structure 120 in the evaporation section 110a and the condensation section 110c.

For example, the pore radius of at least one of the capillary structure 120 in the evaporation section 110a or the capillary structure 120 in the condensation section 110c may be 10 μm, 20 μm, 30 μm, 36 μm, or any value less than 36 μm.

For example, the pore radius of the capillary structure 120 in the adiabatic section 110b is greater than the first threshold, and the first threshold ranges from 30 μm to 36 μm. In this way, the pore radius of the capillary structure 120 in the adiabatic section 110b is made larger, which helps reduce the flow resistance of the heat-conducting working medium in the capillary structure 120 in the adiabatic section 110b.

For example, the first threshold may be 30 μm, 32 μm, 34 μm, 36 μm, or any value between 30 μm and 36 μm.

For example, the pore radius of the capillary structure 120 in the adiabatic section 110b may be 37 μm, 40 μm, 50 μm, 60 μm, or any value greater than 36 μm.

For example, the capillary structure 120 may include at least one of a sintered powder (for example, a sintered metal powder), a metal mesh, or copper foam.

In an implementation in which the capillary structure 120 includes a sintered powder, a mesh size of at least one of a sintered powder in the evaporation section 110a or a sintered powder in the condensation section 110c is greater than a mesh size of a sintered powder in the adiabatic section 110b. In this way, the mesh size of at least one of the sintered powder in the evaporation section 110a or the sintered powder in the condensation section 110c is made larger, and an overall evaporation area of at least one of the sintered powder in the evaporation section 110a or the sintered powder in the condensation section 110c is made larger, thereby helping reduce evaporation thermal resistance (for example, evaporation thermal resistance of the sintered powder in the evaporation section 110a, and/or condensation thermal resistance of the sintered powder in the condensation section 110c). A pore radius of at least one of the sintered powder in the evaporation section 110a or the sintered powder in the condensation section 110c is also made smaller, thereby helping improve capillary force of the sintered powder in the evaporation section 110a and the sintered powder in the condensation section 110c. In addition, the mesh size of the sintered powder in the adiabatic section 110b is made smaller, and a pore radius of the sintered powder therein is made larger, thereby helping reduce the flow resistance of the heat-conducting working medium in the capillary structure 120 in the adiabatic section 110b.

It should be noted that if the mesh size of the powder is larger, a particle size of the powder is smaller, and the pore radius of the sintered powder is smaller.

For example, the mesh size of at least one of the sintered powder in the evaporation section 110a or the sintered powder in the condensation section 110c is greater than or equal to 80, so that the mesh size of at least one of the sintered powder in the evaporation section 110a or the sintered powder in the condensation section 110c is larger, thereby helping improve the capillary force of the sintered powder and reduce thermal resistance. A principle thereof has been described and is not described again.

For example, the mesh size of at least one of the sintered powder in the evaporation section 110a or the sintered powder in the condensation section 110c may be 80, 100, 120, 150, 200, or any value greater than 80.

For example, the mesh size of the sintered powder in the adiabatic section 110b is less than 80, so that the mesh size of the sintered powder in the adiabatic section 110b is smaller, thereby helping reduce the flow resistance of the heat-conducting working medium in the capillary structure 120 in the adiabatic section 110b. A principle thereof has been described and is not described again.

For example, the mesh size of the sintered powder in the adiabatic section 110b may be 20, 40, 60, or any value less than 80.

In an implementation in which the capillary structure 120 includes a metal mesh, a mesh size of at least one of a metal mesh in the evaporation section 110a or a metal mesh in the condensation section 110c is greater than a mesh size of a metal mesh in the adiabatic section 110b, thereby helping improve thermal resistance and capillary force of at least one of the metal mesh in the evaporation section 110a or the metal mesh in the condensation section 110c. In addition, this helps reduce flow resistance of the heat-conducting working medium in the metal mesh in the adiabatic section 110b. A principle thereof has been described and is not described again.

For example, the mesh size of at least one of the metal mesh in the evaporation section 110a or the metal mesh in the condensation section 110c is greater than or equal to 100, so that the mesh size of at least one of the metal mesh in the evaporation section 110a or the metal mesh in the condensation section 110c is larger, thereby helping improve the capillary force of the metal mesh and reduce thermal resistance. A principle thereof has been described and is not described again.

For example, the mesh size of at least one of the metal mesh in the evaporation section 110a or the metal mesh in the condensation section 110c may be 100, 120, 150, 200, or any value greater than 100.

For example, the mesh size of the metal mesh in the adiabatic section 110b is less than 100, so that the mesh size of the metal mesh in the adiabatic section 110b is smaller, thereby helping reduce the flow resistance of the heat-conducting working medium in the capillary structure 120 in the adiabatic section 110b. A principle thereof has been described and is not described again.

For example, the mesh size of the metal mesh in the adiabatic section 110b may be 20, 40, 60, 80, or any value less than 100.

In some embodiments, with reference to FIG. 1, a thickness of at least one of the capillary structure 120 in the evaporation section 110a or the capillary structure 120 in the condensation section 110c is less than a thickness of the capillary structure 120 in the adiabatic section 110b, that is, a thickness of at least one of the first sub-capillary structure 1221 or the third sub-capillary structure 1223 is less than a thickness of the second sub-capillary structure 1222, so that the thickness of at least one of the capillary structure 120 in the evaporation section 110a or the capillary structure 120 in the condensation section 110c is smaller. When the thickness of the capillary structure 120 in the evaporation section 110a is smaller, a thickness of the capillary structure 120 through which bubbles formed by boiling of the liquid working medium need to pass is smaller, and resistance to the bubbles is lower, so that resistance to vapor escape from the capillary structure 120 in the evaporation section 110a is lower. When the thickness of the capillary structure 120 in the condensation section 110c is smaller, resistance to condensation during contact between vapor in the condensation section 110c and an inner wall of the tube body 110 may be reduced. In addition, the thickness of the capillary structure 120 in the adiabatic section 110b may also be made larger, which helps increase a cross-sectional area of the capillary structure 120 in the adiabatic section 110b in a direction perpendicular to the extension direction of the tube body 110, so that flow channels in the capillary structure 120 in the adiabatic section 110b are increased, thereby helping reduce the flow resistance of the heat-conducting working medium in the adiabatic section 110b.

In some other embodiments, the thickness of at least one of the capillary structure 120 in the evaporation section 110a or the capillary structure 120 in the condensation section 110c is equal to the thickness of the capillary structure 120 in the adiabatic section 110b, so that the thickness of the capillary structure 120 is relatively uniform, thereby helping reduce difficulty in manufacturing the capillary structure 120.

In some embodiments, the tube body 110 includes a transition section, and the transition section is disposed in at least one of a portion between the evaporation section 110a or the adiabatic section 110b and a portion between the condensation section 110c and the adiabatic section 110b. The capillary structure 120 in the transition section is disposed in the accommodating cavity 115 corresponding to the transition section.

As shown in FIG. 8, the tube body 110 includes a first transition section 110d and a second transition section 110e. The first transition section 110d connects the evaporation section 110a and the adiabatic section 110b. The second transition section 110e connects the condensation section 110c and the adiabatic section 110b. The thicknesses of the first sub-capillary structure 1221 in the evaporation section 110a and the third sub-capillary structure 1223 in the condensation section 110c may both be less than the thickness of the second sub-capillary structure 1222 in the adiabatic section 110b.

A thickness of a fourth sub-capillary structure 1224 corresponding to the first transition section 110d gradually decreases along a direction from the adiabatic section 110b to the evaporation section 110a, thereby helping avoid a stress concentration area inside the capillary structure 120 caused by an abrupt thickness change of the capillary structure 120 between the evaporation section 110a and the adiabatic section 110b. In addition, this is also beneficial to stable and uniform transmission of the heat-conducting working medium between the evaporation section 110a and the adiabatic section 110b.

A thickness of a fifth sub-capillary structure 1225 corresponding to the second transition section 110e gradually decreases along a direction from the adiabatic section 110b to the condensation section 110c, thereby helping avoid a stress concentration area inside the capillary structure 120 caused by an abrupt thickness change between the condensation section 110c and the adiabatic section 110b. In addition, this is also beneficial to stable and uniform transmission of the heat-conducting working medium between the condensation section 110c and the adiabatic section 110b.

In some embodiments, a pore radius of the capillary structure 120 in the transition section gradually decreases along a direction from the adiabatic section 110b to the transition section, thereby helping avoid an abrupt change in the pore radius of the capillary structure 120 between the evaporation section 110a and the adiabatic section 110b and between the condensation section 110c and the adiabatic section 110b. This is beneficial to stable and uniform transmission of the heat-conducting working medium between the evaporation section 110a and the adiabatic section 110b and between the condensation section 110c and the adiabatic section 110b.

In some embodiments, during manufacturing of the capillary structure 120, a central rod may be inserted into the tube body 110, a sintering material is disposed between the tube body 110 and the central rod, the sintering material is sintered to form the capillary structure 120, and then the central rod is removed.

In some embodiments, with reference to FIG. 2 and FIG. 4, at least one of the capillary structure 120 in the evaporation section 110a or the capillary structure 120 in the condensation section 110c is provided with a groove 121 on a side facing away from the tube body 110, that is, at least one of the first sub-capillary structure 1221 (FIG. 1) or the third sub-capillary structure 1223 (FIG. 1) is provided with a groove 121 on a side facing away from the tube body 110. In this way, a heat exchange area between at least one of the capillary structure 120 in the evaporation section 110a or the capillary structure 120 in the condensation section 110c and the heat-conducting working medium can be increased, thereby helping reduce thermal resistance.

For example, there may be at least one groove. When there are a plurality of grooves 121, the plurality of grooves 121 may be spaced apart. In this embodiment of this application, a plurality of grooves 121 are described as an example.

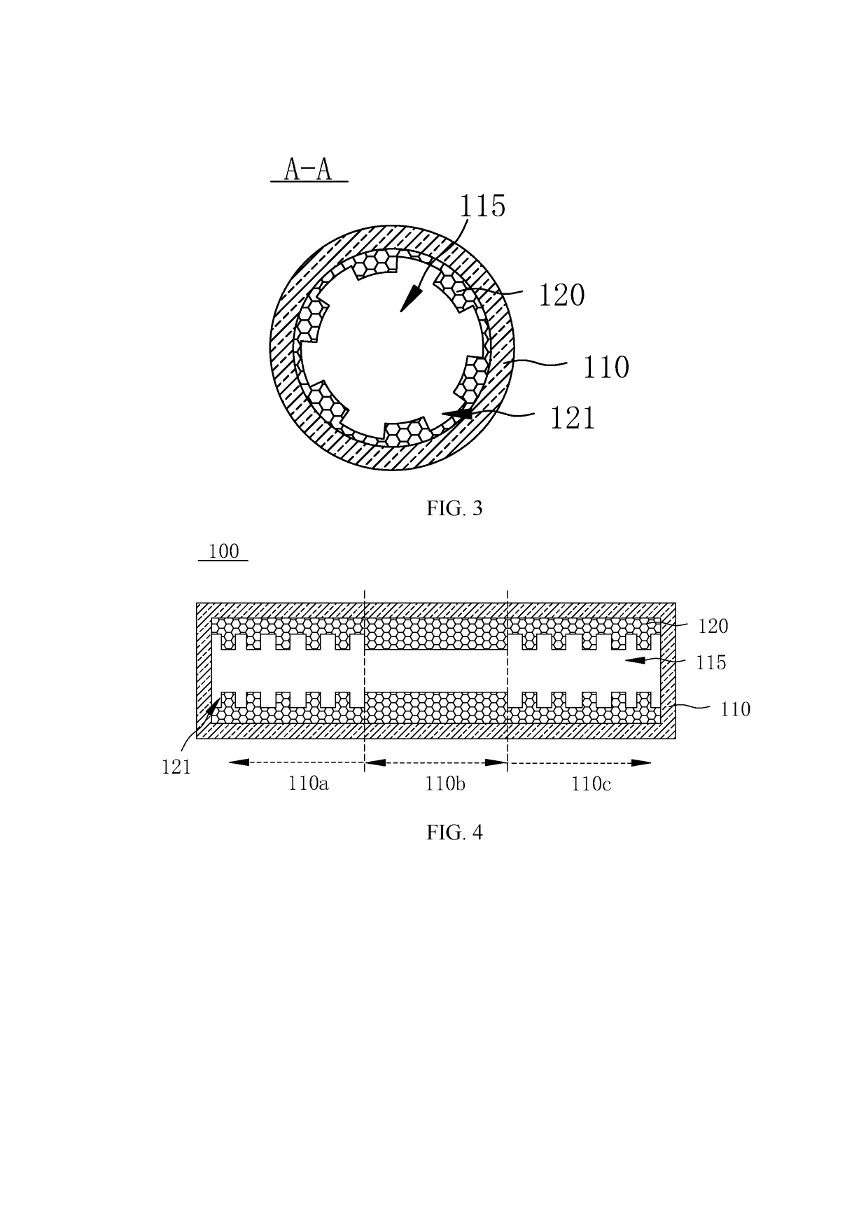

In some examples, with reference to FIG. 2 and FIG. 3, the plurality of grooves 121 extend along the extension direction of the tube body 110, and the plurality of grooves 121 are spaced apart along a circumferential direction of the tube body 110. This helps transmit the gaseous heat-conducting working medium along an extension direction of the grooves 121, and helps increase a transmission rate of the gaseous heat-conducting working medium. In addition, in the process of manufacturing the capillary structure 120, it is relatively easy to remove the central rod from the tube body 110, to reduce the difficulty in manufacturing the capillary structure 120. In some other examples, with reference to FIG. 4, the plurality of grooves 121 extend along the circumferential direction of the tube body 110, and the plurality of grooves 121 are spaced apart along the extension direction of the tube body 110.

For example, an opening dimension of the groove 121 gradually increases in a direction from a groove bottom wall to an opening of the groove 121. For example, a width of the groove 121 gradually increases in the direction from the groove bottom wall to the opening of the groove 121. The capillary structure 120 between two adjacent grooves 121 may form a protruding portion. Along a direction from one of the two adjacent grooves 121 to the other, a thickness of the protruding portion first gradually increases and then gradually decreases, so that a thickness of the protruding portion close to the groove bottom wall of the groove 121 is smaller, thereby reducing resistance to vapor escape from the capillary structure 120 in the evaporation section 110a, and/or reducing the resistance to condensation during contact between the vapor in the condensation section 110c and the inner wall of the tube body 110. In addition, a thickness of the protruding portion away from the groove bottom wall of the groove 121 may be made larger, which is beneficial for increasing an area of the protruding portion, thereby increasing a heat exchange area between the capillary structure 120 and the heat-conducting working medium.

For example, a groove depth of the groove 121 gradually increases in a direction from a center of the tube body to an edge of the tube body in the extension direction of the tube body 110, so that a groove depth of the groove 121 close to an end in the extension direction of the tube body 110 is larger, and a thickness of a part of the capillary structure 120 close to the end in the extension direction of the tube body 110 is smaller, thereby helping reduce the resistance to vapor escape from the capillary structure 120 in the evaporation section 110a and/or reduce the resistance to condensation during contact between the vapor in the condensation section 110c and the inner wall of the tube body 110. In addition, a groove depth of the groove 121 close to the center of the tube body 110 is also made smaller, thereby helping smoothly transmit the heat-conducting working medium in the capillary structure 120 in the adiabatic section 110b to the capillary structure 120 in the evaporation section 110a or the capillary structure 120 in the condensation section 110c.

For example, the groove depth of the groove 121 may range from 0.1 mm to 0.5 mm. For example, the groove depth of the groove 121 may be 0.1 mm, 0.2 mm, 0.4 mm, 0.5 mm, or any value between 0.1 mm and 0.5 mm.

For example, a dimension (that is, a width) of the groove 121 along a direction perpendicular to an extension direction of the groove 121 may range from 0.5 mm to 5 mm. For example, the width of the groove 121 may be 0.5 mm, 1 mm, 3 mm, 5 mm, or any value between 0.5 mm and 5 mm.

In some embodiments, the tube body 110 is provided with a first engaging portion on a side facing toward the capillary structure 120, the capillary structure 120 is provided with a second engaging portion on a side facing toward the tube body 110, one of the first engaging portion and the second engaging portion is an engaging groove, and the other is an engaging protrusion, where the engaging protrusion is disposed in the engaging groove. In this way, through cooperation between the engaging groove and the engaging protrusion, a connection area between the tube body 110 and the capillary structure 120 can be increased, and the capillary structure 120 can also be restrained in position, thereby helping improve connection stability between the tube body 110 and the capillary structure 120.

For example, an opening dimension of the engaging groove gradually decreases along a direction from a groove bottom wall to an opening of the engaging groove, and a shape of the engaging protrusion matches a shape of the engaging groove. In this way, the engaging groove can prevent the engaging protrusion from moving out of the engaging groove, thereby further helping improve the connection stability between the tube body 110 and the capillary structure 120.

For example, along a cross section perpendicular to the extension direction of the tube body 110, a cross-sectional shape of the tube body 110 may be circular, polygonal, elliptical, or other shapes.

For example, the thickness of at least one of the capillary structure 120 in the evaporation section 110a or the capillary structure 120 in the condensation section 110c may range from 0.1 mm to 0.6 mm. For example, the thickness may be 0.1 mm, 0.2 mm, 0.4 mm, 0.6 mm, or any value between 0.1 mm and 0.6 mm.

For example, the thickness of the capillary structure 120 in the adiabatic section 110b may range from 0.2 mm to 0.8 mm. For example, the thickness may be 0.2 mm, 0.4 mm, 0.6 mm, 0.8 mm, or any value between 0.2 mm and 0.8 mm.

In some embodiments, with reference to FIG. 5 and FIG. 6, the tube body 110 includes a first tube wall 111 and a second tube wall 112 that are opposite to each other and spaced apart along a first direction X. The first tube wall 111 is close to the heat-generating element 200, and the first tube wall 111 is in thermal conduction with the heat-generating element 200. A thickness of the capillary structure 120 on the first tube wall 111 is less than a thickness of the capillary structure 120 on the second tube wall 112 in the evaporation section 110a and the adiabatic section 110b. In this way, the capillary structure 120 on the first tube wall 111 in direct contact with the heat-generating element 200 is made thinner, so that resistance to vapor escape from the capillary structure 120 on the first tube wall 111 may be reduced, and better targeted heat dissipation may be performed for the heat-generating element 200. In addition, the thickness of the capillary structure 120 on the second tube wall 112 in the evaporation section 110a and the adiabatic section 110b is larger, so that the return flow of the heat-conducting working medium can be mainly concentrated on the capillary structure 120 on the second tube wall 112. The first direction X intersects with the extension direction of the tube body 110. For example, the first direction X may intersect perpendicularly or obliquely with the extension direction of the tube body 110.

In some embodiments, with reference to FIG. 5, the thickness of the capillary structure 120 on the first tube wall 111 is less than a thickness of the capillary structure 120 on the second tube wall 112 in the condensation section 110c. In this way, the thickness of the capillary structure 120 on the second tube wall 112 in the condensation section 110c is larger, so that the return flow of the heat-conducting working medium can be mainly concentrated on the capillary structure 120 on the second tube wall 112.

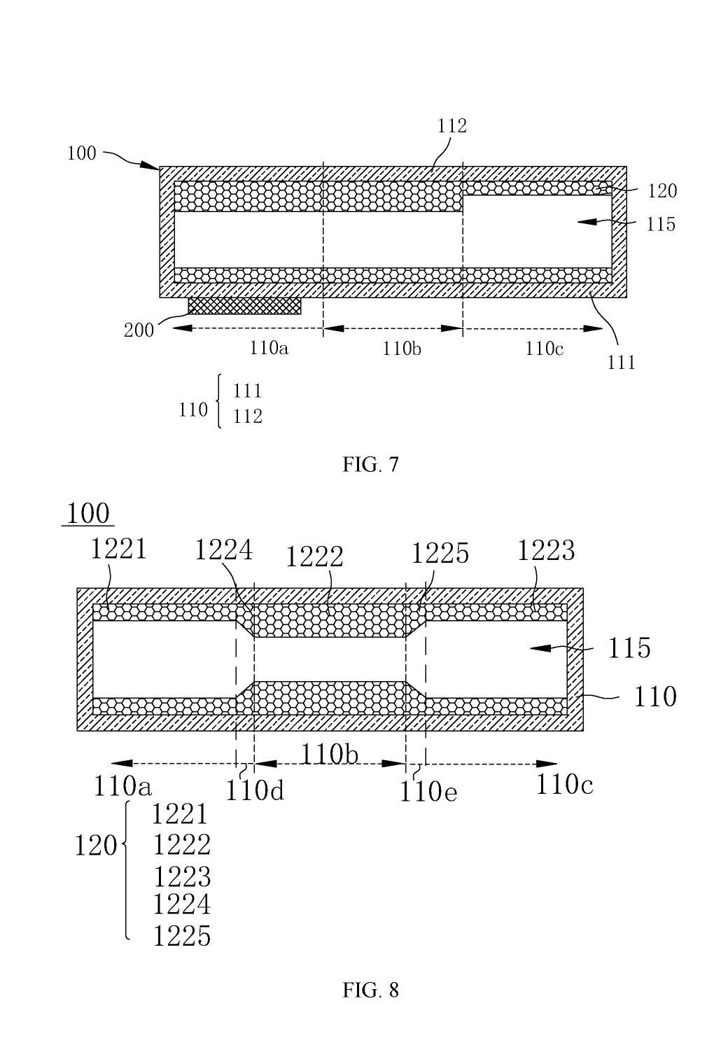

In some other embodiments, with reference to FIG. 6 and FIG. 7, the tube body 110 includes a third tube wall 113 and a fourth tube wall 114 that are opposite to each other and spaced apart along a second direction Y. The third tube wall 113 and the fourth tube wall 114 are both connected to the first tube wall 111 and the second tube wall 112. The thickness of the capillary structure 120 on the second tube wall 112, the third tube wall 113, and the fourth tube wall 114 in the condensation section 110c is less than the thickness of the capillary structure 120 on the second tube wall 112 in the evaporation section 110a and the adiabatic section 110b. In this way, thicknesses of the capillary structure 120 at various positions on the tube wall extending along the circumferential direction of the tube body 110 in the condensation section 110c are all relatively small. The condensation section 110c may be inserted into a heat dissipation element. Resistance to condensation during contact between the vapor in the condensation section 110c and various positions on the inner wall of the tube body 110 is lower, and a contact area between the tube body 110 in the condensation section 110c and the heat dissipation element is larger, so that faster heat dissipation of the condensation section 110c can be achieved.

The heat-conducting working medium in the capillary structure 120 on the second tube wall 112 may be transmitted to the capillary structure 120 on the first tube wall 111 through the capillary structure 120 on the third tube wall 113 and the fourth tube wall 114. Arrows C and D in FIG. 6 show a transmission direction of a part of the heat-conducting working medium.

For example, any two of the first direction X, the second direction Y, and the extension direction of the tube body 110 intersect with each other. For example, any two of the first direction X, the second direction Y, and the extension direction of the tube body 110 may intersect perpendicularly or obliquely.

An embodiment of this application provides an electronic device. With reference to FIG. 7, the electronic device includes a heat-generating element 200 and the heat pipe 100 in the foregoing embodiment. The heat-generating element 200 is in thermal conduction with the evaporation section 110a of the heat pipe 100.

For example, the electronic device may include a network device, a computer, a server, a mobile phone, a tablet, or other electronic devices.

The technical features of the foregoing embodiments may be combined in any way. For brevity of description, not all possible combinations of the technical features of the foregoing embodiments are described. However, as long as there is no contradiction among these combinations of technical features, all the combinations should be considered to fall within the scope described in this specification.

The foregoing embodiments merely represent several implementations of this application, and descriptions thereof are specific and detailed, but should not be construed as a limitation on the scope of the patent of this application. It should be noted that a person of ordinary skill in the art may further make several modifications and improvements without departing from the concept of this application, and these modifications and improvements also fall within the protection scope of this application. Therefore, the protection scope of the patent of this application should be subject to the appended claims.

What is claimed is:

1. A heat pipe, comprising:
a tube body provided with an accommodating cavity, wherein the tube body comprises an evaporation section, an adiabatic section, and a condensation section sequentially arranged along an extension direction of the tube body, and a heat-conducting working medium is provided in the accommodating cavity; and
a capillary structure disposed in the accommodating cavity and connected to the tube body, comprising:
a first sub-capillary structure disposed in the evaporation section;
a second sub-capillary structure disposed in the adiabatic section; and
a third sub-capillary structure disposed in the condensation section, wherein
a pore radius of at least one of the first sub-capillary structure or the third sub-capillary structure is less than a pore radius of the second sub-capillary structure;
wherein the tube body comprises a first tube wall and a second tube wall that are opposite to each other and spaced apart, and the first tube wall is in thermal conduction with a heat-generating element; and
a thickness of a part of the capillary structure on the first tube wall is less than or equal to a thickness of a part of the capillary structure on the second tube wall;
wherein the thickness of the part of the capillary structure on the first tube wall is less than thicknesses of parts of the first sub-capillary structure and the second sub-capillary structure on the second tube wall.

2. The heat pipe according to claim 1, wherein a thickness of at least one of the first sub-capillary structure and the third sub-capillary structure is less than a thickness of the second sub-capillary structure.

3. The heat pipe according to claim 2, wherein the tube body comprises a first transition section, the first transition section connects the evaporation section and the adiabatic section, and the capillary structure further comprises a fourth sub-capillary structure disposed in the first transition section; and
a pore radius of the fourth sub-capillary structure gradually decreases along a direction from the adiabatic section to the evaporation section; and/or
a thickness of the fourth sub-capillary structure gradually decreases along a direction from the adiabatic section to the evaporation section.

4. The heat pipe according to claim 3, wherein the tube body comprises a second transition section, the second transition section connects the condensation section and the adiabatic section, and the capillary structure further comprises a fifth sub-capillary structure disposed in the second transition section; and
a pore radius of the fifth sub-capillary structure gradually decreases along a direction from the adiabatic section to the condensation section; and/or
a thickness of the fifth sub-capillary structure gradually decreases along a direction from the adiabatic section to the condensation section.

5. The heat pipe according to claim 1, wherein at least one of the first sub-capillary structure or the third sub-capillary structure is provided with at least one groove on a side facing away from the tube body.

6. The heat pipe according to claim 5, wherein the at least one groove comprises a first groove, and the first groove extends along the extension direction of the tube body.

7. The heat pipe according to claim 6, wherein the at least one groove further comprises a second groove, the second groove extends along the extension direction of the tube body, and the first groove and the second groove are spaced apart along a circumferential direction of the tube body.

8. The heat pipe according to claim 5, wherein the at least one groove comprises a third groove, and the third groove extends along the circumferential direction of the tube body.

9. The heat pipe according to claim 8, wherein the at least one groove further comprises a fourth groove, and the third groove and the fourth groove are spaced apart along the extension direction of the tube body.

10. The heat pipe according to claim 5, wherein a groove depth of the at least one groove gradually increases in a direction from a center to an edge of the tube body; and/or
an opening dimension of the at least one groove gradually increases in a direction from a groove bottom wall to an opening of the at least one groove.

11. The heat pipe according to claim 1, wherein the tube body comprises a third tube wall and a fourth tube wall that are opposite to each other and spaced apart, and the third tube wall and the fourth tube wall are respectively connected to the first tube wall and the second tube wall to form the accommodating cavity; and thicknesses of parts of the third sub-capillary structure on the second tube wall, the third tube wall, and the fourth tube wall are all less than the thicknesses of the parts of the first sub-capillary structure and the second sub-capillary structure on the second tube wall.

12. The heat pipe according to claim 1, wherein the pore radius of at least one of the first sub-capillary structure or the third sub-capillary structure is less than or equal to a first threshold, and the first threshold ranges from 30 μm to 36 μm.

13. The heat pipe according to claim 1, wherein the pore radius of the second sub-capillary structure is greater than the first threshold, and the first threshold ranges from 30 μm to 36 μm.

14. The heat pipe according to claim 1, wherein the first sub-capillary structure comprises a first sintered powder, the second sub-capillary structure comprises a second sintered powder, and the third sub-capillary structure comprises a third sintered powder; and a mesh size of at least one of the first sintered powder or the third sintered powder is greater than a mesh size of the second sintered powder.

15. The heat pipe according to claim 1, wherein the first sub-capillary structure comprises a first metal mesh, the second sub-capillary structure comprises a second metal mesh, and the third sub-capillary structure comprises a third metal mesh; and a mesh size of at least one of the first metal mesh or the third metal mesh is greater than a mesh size of the second metal mesh.

16. The heat pipe according to claim 1, wherein the tube body is provided with a first engaging portion on a side facing toward the capillary structure, the capillary structure is provided with a second engaging portion on a side facing toward the tube body, and the first engaging portion cooperates with the second engaging portion to fasten the capillary structure to the tube body.

17. The heat pipe according to claim 16, wherein one of the first engaging portion and the second engaging portion is an engaging groove, and the other is an engaging protrusion, wherein the engaging protrusion is disposed in the engaging groove, and preferably, an opening dimension of the engaging groove gradually decreases along a direction from a groove bottom wall to an opening of the engaging groove.

18. An electronic device, comprising a heat-generating element and the heat pipe according to claim 1, wherein the heat-generating element is in thermal conduction with the evaporation section of the heat pipe.
